(19) United States
(12) Patent Application Publication
(10) Pub. No.: US 2019/0237647 A1
(43) Pub. Date: Aug. 1, 2019

(54) METHOD OF MANUFACTURING THERMOELECTRIC MODULE USING INK FORMULATIONS

(71) Applicants: Cambridge Display Technology Limited, Godmanchester (GB); Sumitomo Chemical Company Limited, Tokyo (JP)

(72) Inventor: Thomas Fletcher, Godmanchester (GB)

(73) Assignees: Cambridge Display Technology Limited, Godmanchester (GB); Sumitomo Chemical Company Limited, Tokyo (JP)

(21) Appl. No.: 16/331,014

(22) PCT Filed: Aug. 29, 2017
(86) PCT No.: PCT/GB2017/052515

§ 371 Date: Mar. 6, 2019

(30) Foreign Application Priority Data
Sep. 7, 2016 (GB) 1615154.0

(51) Int. Cl. H01L 35/24; H01B 1/12; C08G 61/12

(52) U.S. Cl. CPC H01L 35/24; H01B 1/127; C08K 5/315; C08G 2261/792; C08G 61/126

(57) ABSTRACT

A method of manufacturing a conductive layer includes the step of dissolving an organic semiconductor polymer in a first solvent, the first solvent being an aromatic or heterocyclic compound comprising one or more electron-rich carbon atom(s) and/or heteroatom(s). The method also includes dissolving a dopant in a second solvent, the second solvent being a polar solvent. The method also includes mixing the solutions of the organic semiconductor polymer and the dopant to form a dispersion comprising doped conductive polymer particles suspended in the solvent blend. The method also includes depositing the dispersion by a solution deposition technique to form a conductive layer. The solution deposition technique is preferably an inkjet printing, dispense printing or drop casting method. The dispersion provides a stable ink composition for the manufacturing of thick and uniform layers with excellent conductivity and thermopower, and allows simple fabrication of thermoelectric legs with enhanced performance.

### FIELD OF INVENTION

This invention relates to a formulation comprising a dispersion of a doped conductive polymer in a blend of at least two solvents which is particularly useful as a stable ink formulation for solution deposition of highly conductive layers, e.g. in thermoelectric modules. In addition the present invention relates to a method of manufacturing conductive layers, conductive layers produced by said method and to thermoelectric modules comprising said conductive layers, e.g. as thermoelectric legs.

### BACKGROUND OF THE INVENTION

Organic thermoelectrics have attracted considerable research interest since they enable realization of flexible, large-area modules which may be manufactured and processed at low costs by using solution processing techniques.

In general, the fabrication of a thermoelectric module involves the formation of p- and n-type semiconducting legs that are usually connected in series to the applied electric field and parallel to the heat gradient applied over the generator module.

Printing of organic semiconductor polymers offers a particularly inexpensive route to development of such modules (see R. R. Sondergaard et al., Energy Sci. Eng. 2013, 1, 81).

In the recent years, many efforts have been made to develop new p- and n-type polymers which are both amenable to solution processing and exhibit a favourable thermoelectric performance, i.e. optimized electronic conductivity, power factor and Seebeck coefficient and a low heat conductivity. While organic polymers typically exhibit a low thermal conductivity compared to most inorganics, doping of the polymer backbone is required in order to achieve a high conductivity within these materials. However, in thermoelectric organic materials there is a well-known trade-off between electrical conductivity and Seebeck coefficient, which severely limits the development of organic thermoelectric generators.

Several doped thiophene-based polymers have been shown to yield promising results. For example, the n-type polymer P(NDIOD-T2), in combination with a dihydro-1H-benzoimidazol-2-yl (N-DBI) derivative as a dopant, has been shown to achieve electrical conductivities of nearly 0.01 S·cm⁻¹ (see R. A. Schlitz et al., Adv. Mater. 2014, 26, 2825).

Recently, conjugated thiophene-based p-type polymers PQT12, P3HT, and PBTTT-C14 doped with weakly oxidizing metal acetylacetonate complexes have been proposed as materials with both promising electrical conductivities (up to 0.01 S·cm⁻¹) and Seebeck coefficients (see R. Ireland, “Demonstration of Weak Sild Doping Concept for Simultaneous Conductivity and Seebeck Coefficient Increase in P-type Polymer Composites”, MRS 20015, Symposium M1.04).

While it is widely known that the choice of processing solvents may generally have a significant influence on the morphology of the solution-deposited conductive layer, the deposition of doped conductive polymers is particularly challenging from the viewpoint of solvent selection.

For example, a number of solvents which may otherwise represent suitable candidates for printing ink compositions tend to exhibit poor drying properties and/or a high toxicity, such as halogenated solvents (e.g. chlorobenzene, dichlorobenzenes).

In addition to the above, mixing a semiconductive polymer with a dopant usually alters its solubility properties, e.g. by formation of a charge-transfer complex or an ion pair which may be insoluble in the primary solvent. In order to process such materials, the polymer and dopant are thus often mixed in a solvent and deposited onto a substrate in a very short timeframe in order to keep precipitation at a minimum and thereby prevent blocking of printing nozzles and/or non-uniform deposition. However, a large number of applications require extended printing times. For instance, in order to provide thermoelectric legs with a sufficient layer thickness, multiple printing passes are required, which may extend the printing process to the range of hours, during which increased precipitation may occur. On the other hand, the conventional approach of avoiding precipitation by reducing the solids content in the ink composition is not suitable for the printing of thick layers. Accordingly, ink compositions prone to precipitation cannot be used with satisfactory results.

In view of the above, there exists a need to provide a composition which may be used as a stable, print-friendly and environmentally friendly ink and which allows multipass deposition of conductive layers. Moreover, it remains desirable to provide conductive layers having simultaneously improved conductivity, Seebeck coefficient and uniformity and which may be used in the manufacture of thermoelectric modules, e.g. as thermoelectric legs.

### SUMMARY OF THE INVENTION

The present invention solves these objects with the subject matter of the claims as defined herein. The advantages of the present invention will be further explained in detail in the section below and further advantages will become apparent to the skilled artisan upon consideration of the invention disclosure.

The present inventors found that by mixing a solution of semiconductive polymer in an electron-rich solvent and a dopant in a polar solvent, a stable dispersion comprising doped polymer particles suspended within the solvent blend may be formed which allows to use high solids contents and enables multi-pass printing of conductive layers having an excellent electrical conductivity. Accordingly, thick conductive films such as thermoelectric legs may be deposited by a printing or dispensing method and thermoelectric modules with improved performance may be provided.

Generally speaking, the present invention relates to a method of manufacturing a conductive layer, the method comprising the steps of: dissolving an organic semiconductor polymer in a first solvent, the first solvent being an aromatic or heterocyclic compound comprising one or more electron-rich carbon atom(s) and/or heteroatom(s); dissolving a dopant in a second solvent, the second solvent being a polar solvent; mixing the solutions of the organic semiconductor polymer and the dopant to form a dispersion comprising doped conductive polymer particles suspended in the solvent blend; and depositing the dispersion by a solution deposition technique to form a conductive layer, preferably by an inkjet printing, dispense printing or drop casting method.

In second and third aspects, the present invention relates to a conductive layer manufactured by the aforementioned method and a thermoelectric module comprising said conductive layer.

In a further aspect, the present invention relates to a formulation comprising a doped conductive polymer dispersed in a solvent blend, the solvent blend comprising a first solvent and a second solvent, wherein the first solvent is an aromatic compound comprising one or more electron-rich aromatic carbon(s) or a heterocyclic compound comprising one or more electron-rich heteroatom(s) in the heterocycle, and wherein the second solvent is a polar solvent excluding water, the polar Hansen Solubility Parameter δ_{P} of the second solvent being higher than 8.0.

In a further aspect, the present invention relates to use of the aforementioned formulation in a solution deposition method, preferably an inkjet printing method.

Preferred embodiments of the formulation according to the present invention and other aspects of the present invention are described in the following description and the claims.

### BRIEF DESCRIPTION OF THE DRAWINGS

FIG. 1 schematically illustrates the general architecture of a thermoelectric generator.

FIG. 2 schematically illustrates the device configuration used for conductivity measurements.

FIG. 3 schematically illustrates the device configuration used for Seebeck coefficient determination.

FIG. 4 is a graph showing the linear regression of the generated voltage in dependence of the temperature difference.

### DETAILED DESCRIPTION OF THE INVENTION

For a more complete understanding of the present invention, reference is now made to the following description of the illustrative embodiments thereof:

### Ink Formulation

In a first embodiment, the present invention relates to a formulation comprising a doped conductive polymer dispersed in a solvent blend, the solvent blend comprising a first solvent and a second solvent, wherein the first solvent is an aromatic compound comprising one or more electron-rich aromatic carbon(s) or a heterocyclic compound comprising one or more electron-rich heteroatom(s) in the heterocycle, and wherein the second solvent is a polar solvent excluding water, the polar Hansen Solubility Parameter δ_{P} of the second solvent being higher than 8.0.

According to the present invention, the first and the second solvents are different, and the solvent blend comprises at least said two solvents or consists of those two solvents.

The doped conductive polymer is an organic semiconductor polymer, the polymer backbone of which has been subjected to n- or p-type doping by use of dopants known in the art. Molecular doping of an organic semiconductor is generally described by two fundamental mechanisms of interaction between the dopant and the organic semiconductor matrix, i.e. ion pair formation and the formation of a ground state charge-transfer complex, both of which result in an increase of the charge carrier concentration and hence electrical conductivity. In either case, doping of organic semiconductors involves chemical oxidation or reduction of the organic semiconductive material which results in formation of charge carriers. As indicated above, this process dramatically changes the solubility of the organic semiconductor form that of the neutral form, which imposes severe practical limitations on the processing parameters and the quality and performance of the resulting conductive layers and films. These difficulties have been conventionally dealt with by limiting the level of dopant added to the casting solution in order to avoid precipitation in the casting film. Alternatively, an organic semiconducting film has been soaked in a non-solvent containing the dopant, which is, however, impractical for manufacturing thick films as the diffusion of the dopant through the polymer layer is often ineffective or slow. It has been found that these disadvantages may be overcome by the formulation of the present invention. Namely, since the doped conductive polymer is dispersed in a solvent blend comprising a first, electron-rich solvent and a second, polar solvent, a stable ink is provided which allows the use of high doping levels with no or reduced precipitation, so that it becomes possible to deposit thick films (e.g. by multi-pass printing) without compromising the quality (i.e. conductivity, morphology and uniformity) of the deposited conductive films or layers.

The organic semiconductor polymer used for the generation of the doped conductive polymer is not particularly limited and may be selected from conjugated polymers known in the art. The organic semiconductor polymer typically includes conjugated polymers formed by polymerization or co-polymerization of monomer units including, but not limited to thiophene, pyrrole, aniline, acetylene, p-phenylene, p-phenylenevinylene, p-phenyleneethynylene, p-fluorenylenevinylene, p-fluorene, arylamine, polyacene, polyphenanthrene compound, metal-phthalocyanine, p-xylylene, vinylenesulfide, m-phenylene, naphthalenevinylene, a p-phenyleneoxide, phenylenesulfide, furan, selenophene, and derivatives thereof. Preferably, the organic semiconductor polymer is a conjugated polymer obtained by polymerization or copolymerization of at least one compound or derivative selected from the group consisting of a thiophene compound, a pyrrole compound, an aniline compound, an acetylene compound, a p-phenylene compound, a p-phenylenevinylene compound, a p-phenyleneethynylene compound, a fluorene compound, an arylamine compound, and derivatives thereof. Further preferably, the organic semiconductor polymer is a thiophene-based conjugated polymer, i.e. a conjugated polymer having a thiophene compound or a derivative thereof as repeating structures. Examples thereof include polythiophene containing a repeating structure derived from thiophene, a conjugated polymer containing a repeating structure derived from a derivative of a thiophene compound having a substituent introduced into a thiophene ring, and a conjugated polymer containing a repeating structure derived from a thiophene compound having a condensed polycyclic structure including a thiophene ring. As specific examples of the thiophene-based conjugated polymer, poly-3-methylthiophene, poly-3-butylthiophene, poly-3-hexylthiophene (P3HT), poly-3-cyclohexylthiophene, poly-3-(2′-ethylhexyl)thiophene, poly-3-octyithiophene, poly-3-dodecylthiophene, poly-3-(2′-methoxyethoxy)methylthiophene, poly-3-(methoxyethoxyethoxy)methylthiophene; poly-3-methoxythiophene, poly-3-ethoxythiophene, poly-3-hexyloxythiophene, poly-3-cyclohexyloxythiophene, poly-3-(2-ethylhexyloxy)thiophene, poly-3-dodecyloxythiophene, poly-3-methoxy(diethyleneoxy)thiophene, poly-3-methoxy(triethyleneoxy)thiophene, poly-(3,4-ethylenedioxythiophene) (PEDOT), poly(3,3′″-didodecylquaterthiophene) (PQT12), poly-3-methoxy-4-methylthiophene, poly-3-hexyloxy-4-methylthiophene, poly-3-dodecyloxy-4-methylthiophene, poly-3-thiohexylthiophene, poly-3-thiooctylthiophene, poly-3-thiododecylthiophene, poly[N,N′-bis(2-octyl-dodecyl)-1,4,5,8-naphthalenedicarboximide-2,6-diyl]alt-5,5′-(2,2′-bithiophene)] (P(NDIOD-T2)), and poly(2,5-bis(3-alkyl-thiophene-2-yl) thieno-[3,2-b]-thiophene (PBTTT) polymer (including e.g. PB10TTT, PB12TTT, PB14TTT and PB16TTT) may be mentioned. Further preferably, the thiophene-based conjugated polymer is selected from poly-3-hexylthiophene (P3HT) and/or poly(3,3″-didodecylquaterthiophene) (PQT12).

The dopant is likewise not particularly limited as long as it is capable of inducing the formation of charge carriers in the organic semiconductor polymer and may be selected form n- and p-type dopants known in the art.

A number of suitable p-type dopants is disclosed in US 2016/0013392 A1, for example. Preferably, the p-type dopant is selected from the group of electron acceptors. As examples thereof, TCNQ (tetracyanoquinodimethane), halogenated tetracyanoquinodimethane (including e.g. tetrafluorotetracyanoquinodimethane (F4TCNQ)), 1,1-dicyanovinylene, 1,1,2-tricyanovinylene, benzoquinone, pentatluorophenol, dicyanotluorenone, cyano-fluoroalkylsulfonyl-fluorenone, pyridine, pyrazine, triazine, tetrazine, pyridopyrazine, benzothiadiazole, heterocyclic thiadiazole, porphyrin, phthalocyanine, and boron atom-containing compounds may be mentioned. Preferably, the p-type dopant has a LUMO level of less than −4.3 eV relative to the vacuum level, as may be measured by square wave voltammetry, for example. Further preferably, the p-type dopant is an optionally substituted tetracyanoquinodimethane (TCNQ), most preferably tetrafluorotetracyanoquinodimethane (F4TCNQ).

N-type dopants may be selected from electron donors or reducing agents. As examples thereof, imidazol derivatives (e. g. dihydro-1H-benzoimidazol-2-yl (N-DBI)), metal acetylacetonate complexes (e.g. Co(acac)₃, Fe(acac)₃, Mn(acac)₃) and inorganic reducing agents (e.g. SnCl₂) may be mentioned.

Preferably, the polymer:dopant weight ratio in the doped conductive polymer is in the range of from 5:1 to 20:1, more preferably in the range of from 7:1 to 12:1.

The first solvent is an aromatic compound comprising one or more electron-rich aromatic carbon(s) or a heterocyclic compound comprising one or more electron-rich heteroatom(s) in the heterocycle. It has been found that the use of electron-rich solvents efficiently promotes high electron conductivity in the resulting deposited layers. In general, the expression “electron-rich aromatic carbon”, as used herein, denotes aromatic carbon atoms which exhibit an increased 7-electron density relative to a benzene carbon. In the context of heterocyclic compounds the expression “electron-rich heteroatom” denotes a heteroatom (e.g. oxygen, nitrogen or sulfur) having unpaired electrons which may contribute to a 7-electronic system. Exemplary electron-rich heterocycles include, but are not limited to, pyrrole, indole, furan, benzofuran, thiophene, benzothiophene and other similar structures.

Preferably, the first solvent is selected from the group of C₆-C₁₈ aromatic hydrocarbons comprising one or more electron-donating (activating) substituents or C₄-C₁₈ heterocyclic compounds which may be unsubstituted or comprise one or more electron-donating substituents. More preferably, the first solvent is a C₆-C₁₈ aromatic hydrocarbon comprising one or more electron-donating substituents. The electron-donating groups are not particularly limited and may be appropriately selected by the skilled artisan. As examples thereof, C₁-C₁₂ alkyl groups and/or C₁-C₁₂ alkoxy groups may be mentioned. Particularly preferred examples of the first solvent are benzenes having one to six substituents selected from C₁-C₆ alkyl groups and/or C₁-C₆ alkoxy groups. Specific examples thereof include o-xylene, m-xylene, p-xylene, 1,2,4-trimethylbenzene, 1,2,4-triethylbenzene, 1,2-dimethyl-4-ethylbenzene, 1,2,3-trimethylbenzene, 1,2,3-triethylbenzene, anisole, 4-methylanisole, 1,2-dimethoxybenzene (veratrol), 1,3-dimethoxybenzene, 1,2-diethoxybenzene, etc.

In a preferred embodiment, the first solvent exhibits a boiling point of 175° C. or lower.

The formulation of the present invention preferably comprises the first solvent in a content of from 40 to 99 vol.-%, more preferably from 50 to 95 vol.-%, further preferably from 60 to 90 vol.-%.

As will be described in further detail below, the first solvent is used to dissolve the organic semiconductor polymer prior to mixing of the dopant solution and preparing the dispersion. Accordingly, in order to provide for sufficient dissolution of the polymer, the skilled artisan will typically choose compounds having low polarity as the first solvent. Usually, the polar contribution Hansen Solubility Parameter Op of the first solvent will be 10.0 or lower, in embodiments lower than 8.0. The dispersion contribution OD of the first solvent is preferably within the range of 17 to 22, more preferably within the range of 18 to 19.2; and the hydrogen bonding contribution OH of the first solvent is preferably within the range of 0 to 10, more preferably within the range of 1.0 to 9.5. Hansen Solubility Parameters can be determined according to the HSPiP program (Versions 4.1 or 5.0) as supplied by Hansen and Abbot et al. Values of Hansen parameters and details regarding their calculation can be found in C. M. Hansen, “Hansen Solubility Parameters: A User's Handbook”, 2^{nd} Ed. 2007, Taylor and Francis Group LLC. Mixing a polymer and dopant in a non-polar/low-polar solvent alone would result in precipitation of the doped species, whereas mixing of the polymer and dopant in a high polarity solvent alone would prevent the organic semiconductor polymer from dissolving in the first place. According to the present invention, the formation of a stable dispersion is enabled by previously dissolving the dopant in the second, polar solvent and subsequent mixing of the solution.

The second solvent is not water and is preferably an aprotic polar solvent.

The polar Hansen Solubility Parameter Op of the second solvent is higher than 8.0, preferably higher than 9.0, more preferably higher than 10.0. Suitable solvents may be identified according to the HSPiP program or from literature (see e.g. Appendix of C. M. Hansen, “Hansen Solubility Parameters: A User's Handbook”, 2^{nd} Ed. 2007, Taylor and Francis Group LLC).

In another preferred embodiment, the second solvent is an organic compound comprising one or more aldehyde, ketone, carboxylic acid, ester, hydroxyl, nitrile, amide, amino, thioester, and/or thiol group(s).

As especially preferred examples falling into the above definitions of the second solvent, acetone and acetonitrile may be mentioned.

The formulation of the present invention preferably comprises the second solvent in a content of from 1 to 60 vol.-%, more preferably from 5 to 50 vol.-%, further preferably from 10 to 40 vol.-%.

In a preferred embodiment, the solvent blend comprises the first solvent and the second solvent in a volume ratio of from 40:60 to 99:1, preferably from 50:50 to 90:10, further preferably from 60:40 to 80:20.

Typically, the formulation according to the present invention has a solids content of from 0.05 to 5.0% w/v, preferably from 0.5 to 3.0% w/v, further preferably from 1.0 to 2.0% w/v.

While it may be preferable that the solvent blend consists of the first and the second solvent, the solvent blend may comprise one or more further solvents which are not particularly limited and may be appropriately selected by the skilled artisan.

In a preferred embodiment, the formulation of the present invention comprises a third solvent, which is likewise an aromatic or heterocyclic compound comprising one or more electron-rich carbon atom(s) and/or heteroatom(s) in accordance with the above description of the first solvent, but differs from and complements the first solvent with respect to the boiling point characteristics. For example, if the first solvent exhibits a boiling point of 175° C. or lower, it is preferable that the third solvent has a boiling point above 175° C. Such a configuration may further promote the conductivity of the resulting layer.

As alternative solvents which may be added to the solvent blend, linear or cyclic ketones (e.g. cyclohexanone), aromatic and/or aliphatic ethers (e.g. anisole), aromatic alcohols, optionally substituted thiophenes, benzothiophenes, alkoxylated naphthalene, substituted benzothiazoles, alkyl benzoates, chlorinated solvents (e.g. chlorobenzene, trichlorobenzene, dichlorobenzene or chloroform) and mixtures thereof may be mentioned. In another preferred embodiment, said additional solvents are comprised at a total content of less than 3 vol.-%, more preferably less than 2 vol.-% relative to the total solvent volume.

From the viewpoint of environment-friendliness it is preferred that the formulation of the present invention does not contain chlorinated solvents.

The formulation may comprise further components in addition to the doped conductive polymer and the solvent blend. As examples for such components, adhesive agents, de-foaming agents, deaerators, viscosity enhancers, diluents, auxiliaries, flow improvers colourants, dyes or pigments, sensitizers, stabilizers, nanoparticles, surface-active compounds, lubricating agents, wetting agents, dispersing agents and inhibitors may be mentioned.

It will be appreciated that the preferred features of the first embodiment specified above may be combined in any combination, except for combinations where at least some of the features are mutually exclusive.

The above-defined formulations serve as a starting material for the solution deposition of conductive layers and films which have an advantageously high stability for solution deposition applications, which are resistant to precipitation and allow manufacturing of thick and uniform layers with improved conductivity.

### Conductive Layers, Thermoelectric Modules and Methods for Manufacturing the Same

In a second embodiment, the present invention relates to a method of manufacturing a conductive layer, the method comprising the steps of: dissolving an organic semiconductor polymer in a first solvent, the first solvent being an electron-rich organic compound comprising one or more electron-donating groups; dissolving a dopant in a second solvent, the second solvent being a polar solvent; mixing the solutions of the organic semiconductor polymer and the dopant to form a dispersion comprising doped conductive polymer particles suspended in the solvent blend; depositing the dispersion by a solution deposition technique; and removing the solvent blend to form a conductive layer.

Preferred embodiments of the organic semiconductor polymer, the dopant, the first and the second solvents are set out in the above description of the first embodiment.

In order to provide a favourably even dispersion, it is preferable that after the step of mixing the solutions of the organic semiconductor polymer and the dopant, the mixture is subjected to a sonication step, e.g. an ultra-sonication step.

The solution deposition technique includes but is not limited to coating or printing or micro-dispensing methods like for example spin coating, spray coating, web printing, brush coating, dip coating, slot-die printing, ink jet printing, letter-press printing, screen printing, doctor blade coating, roller printing, offset lithography printing, flexographic printing, or pad printing. Preferably, the solution deposition method is an inkjet printing, dispense printing or drop casting method, more preferably a dispense printing or an inkjet printing method. Inkjet printing generally involves the ejection of a fixed quantity of a liquid phase, i.e. ink, in form of droplets from a chamber through a nozzle. The ejected drops are provided onto a substrate to form a pattern. While solidification of the liquid drops may be brought about through chemical changes or crystallization, solvent evaporation is commonly used, in some cases by exposing the deposited wet film to high temperature and/or reduced pressure, preferably immediately upon printing.

The specified method has the advantage that it enables fabrication of thick conductive layers, as multiple printing passes may be carried out without the danger of precipitation of the active material during the deposition (avoiding nozzle clogging, for example) and deposition of a non-uniform layer may be avoided. Thus, in contrast to conventional methods, highly doped polymer layers may be easily and quickly formed at high thicknesses and without the use of solvents that are of environmental concern.

The third embodiment of the present invention is a conductive layer manufactured by the method in accordance to the second embodiment. The conductive layer produced accordingly simultaneously exhibits high uniformity, excellent conductivity, and a high Seebeck coefficient. The electrical conductivity of the conductive layer, which may be measured in accordance to methods known to the skilled artisan, is 0.1 S/cm or more, in embodiments 0.3 S/cm or more or 0.5 S/cm or more. The absolute value of the Seebeck coefficient of the conductive layer is at least 40 pV/K, in embodiments at least 50 pV/K. The Seebeck coefficient, which represents a measure of the magnitude of an induced thermoelectric voltage in response to a temperature difference across the material, may likewise be measured by methods known in the art. Typically, the Seebeck coefficient of a material is measured by placing the thermoelectric material in between two conducting metal (e.g. Cu) blocks, heating one end of the sample material (which has the effect that the opposed end acts as a heat sink, dispersing the heat, thus cooling that side), placing thermocouples on the thermoelectric material between the metal blocks, registering the temperature difference in the material and the voltage drop via the thermocouples, and determining therefrom the Seebeck coefficient.

Since the solvent blend used in the formulation of the present invention decisively influences the uniformity and morphology of the resulting conductive layer, the latter exhibits characteristic properties (e.g. texture). Also, residual amounts of solvents, particularly of those having high boiling points (e.g. 175° C. or higher) may be found in the conductive layer even after extensive drying and hence contribute to distinct structural properties.

The thickness of the conductive layer may be appropriately set by the skilled artisan depending on its purpose and application and generally ranges between 20 nm to 100 μm.

In a fourth embodiment of the present invention, the conductive layer according to the third embodiment is comprised in the thermoelectric leg of a thermoelectric module.

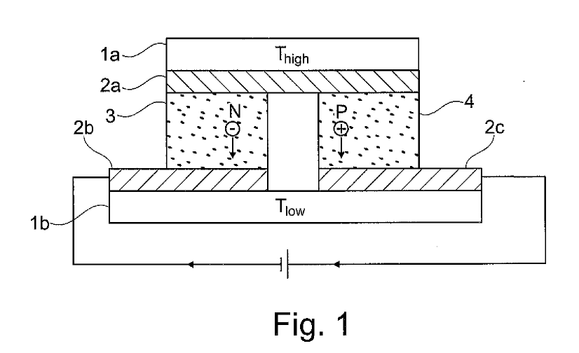

A general schematic representation of an exemplary thermoelectric module is depicted in FIG. 1. An exemplary module comprises one or a plurality of thermoelectric junctions between an n-type material and p-type material having different Seebeck coefficients, which generally take the shape of n-type (3) and p-type (4) legs arranged between electrically-insulating substrates (1a and 1b), optionally with conductor layers/electrical shunt layers (2a, 2b and 2c) or interface material layers (not depicted) provided in between. Such junctions particularly enable to generate electric power when they are submitted to a temperature gradient (as that between the upper high temperature side and the lower low temperature side in FIG. 1, for example), or to generate heat when they are crossed by an electric current.

When used as a thermoelectric leg, the thickness of the conductive layer is preferably in a range of from 0.5 to 800 μm, more preferably from 1 to 500 μm, and further preferably from 5 to 100 μm.

The thermoelectric module according to the fourth embodiment combines the typical advantages of organic thermoelectrics, i.e. enables realization of flexible, large-area modules which may be manufactured and processed at low costs by using solution processing techniques, and at the same time exhibits excellent thermoelectric conversion performance.

In a fifth embodiment, the present invention relates to the use of the formulation according to the above-described first embodiment in the manufacturing of a thermoelectric module.

### EXAMPLES

### Conductivity Tests and Solvent Selection

Initially, the conductivity (a) of thin conductive layers manufactured by deposition of highly conductive poly(3,3m-didodecylquaterthiophene) (PQT12) polymer doped with tetrafluorotetracyanoquinodimethane (F4TCNQ) from a selection of solvent systems has been measured (each under identical conditions).

For this purpose, DC resistance was first measured in a 4 point probe configuration using a Keithley Sourcemeter 2400 by contacting electrode leadouts provided on the respective conductive layer; the sourcemeter was configured to automatically select appropriate current source and measurement range (2 kOhm, 1 mA). The layer thicknesses were then measured by removing a portion of the film and measuring the step height of the surface profile (Dektak V400-Si). The conductivity was then calculated from the formula:

$$σ = \frac{wt}{Rl}$$

wherein σ is conductivity, w is the length of the electrode formed by the conductive layer (10 mm), t is the thickness, R is the resistance and 1 is the spacing (1-4 mm).

The results of the measurements are shown in Table 1.

TABLE 1
Conductivities of PQT12:F4TCNQ layers
in dependence of deposition solvent.

| | Electron rich, low b.p. | Electron poor, low b.p. |
|---|---|---|
| Electron rich, | Trimethylbenzene | Cyclopentanone |
| high b.p. | (b.p. ~170° C.) | (b.p. 131° C.) |
| | Veratrol (b.p. 207° C.) | Veratrol (b.p. 207° C.) |
| | σ = 0.75 S/cm | σ = 0.07 S/cm |
| Electron poor, | 4-methylanisole | Cyclopentanone |
| high b.p. | (b.p. ~170° C.) | (b.p. 131° C.) |
| | Butyl benzoate | ODCB (b.p. 179° C.) |
| | (b.p. 249° C.) | σ = ~10⁻⁵ S/cm |
| | σ = 0.31 S/cm | |

As is demonstrated by Tab. 1, layers deposited by using electron-rich solvents such as trimethylbenzene (θ_{D}=18.0; δ_{P}=1.0; δ_{H}=1.0); Veratrol (1,2-dimethoxybenzene (δ_{D}=19.2; δ_{P}=4.4; δ_{H}=9.4)) and 4-methylanisole (δ_{D}=18.6; δ_{P}=5.9; δ_{H}=7.2) lead to improved conductivities when compared to layers deposited by use of electron-poor solvents, such as cylcopentanone (δ_{D}=17.9; δ_{P}=11.9; δ_{H}=5.2), butyl benzoate (δ_{D}=20.0; δ_{P}=5.1; δ_{H}=5.2) or ODCB (o-dichlorobenzene; δ_{D}=19.2; δ_{P}=6.3; δ_{H}=3.3)). The results further suggest that the solvent having a boiling point of 175° C. or lower has a major impact on the resulting film conductivity.

### Ink Formulation and Conductive Layer Deposition

### Example 1

A dispersion has been prepared by separately dissolving PQT12 in 1,2,4-trimethylbenzene (TMB; δ_{D}=18.0; δ_{P}=1.0; δ_{H}=1.0) as the first solvent at a concentration of 1.29% w/v, and the dopant F4TCNQ in acetonitrile (δ_{P}=18.0) as the second solvent at a concentration of 0.33% w/v. The dissolution of PQT12 has been accelerated by heating to 80° C. The solutions were then combined with mixing and subjected to sonication at 37 kHz for 1 hour, resulting in a stable dispersion having a polymer:dopant ratio of 9:1 by weight and TMB:acetonitrile ratio of 7:3 by volume, the dispersion comprising doped polymer particles suspended within the solvent blend and having a solids content of 1%.

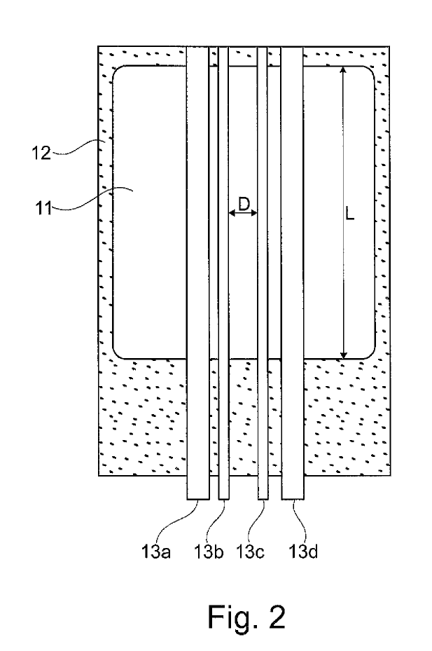

Thereafter, devices having a configuration in accordance with FIG. 2 have been manufactured. For this purpose, substrates have been prepared by evaporating or sputtering onto glass a layer of chrome/gold or AgBiGe, respectively. These were patterned by photolithography to form 4 point probe electrode contacts (with additional leadouts) having widths of 200 μm and 500 μm for the sense electrodes (13b and 13c) and source electrodes (13a and 13d) respectively, with a spacing D of 1, 2, 3 or 4 mm between the sense probes 13a and 13b. Additionally a polymer insulating layer 12 (a bank) was deposited by spin coating onto the substrate and photo-patterned to form rectangular open areas above the electrodes 13a to 13d, thus limiting the exposed length of electrode to 10 mm.

The doped polymer ink was deposited via dispense printing, using Asymtek Dispensemate 580 interfaced with a nanoliter syringe pump (Cole Parmer KDS310) to control dispensing. The open area within the bank was filled using a square spiral pattern with continuous dispensing such that the deposited ink fully covered the open area 11 and electrodes. The deposited ink was then dried by evaporation in ambient atmosphere aided by heating (at temperatures of 50-80° C.) resulting in a film covering the electrodes with thickness of 3.5 μm.

In line with the description above, DC resistance was measured in a 4 point probe configuration using a Keithley Sourcemeter 2400 by contacting the electrode leadouts on the substrate and the layer thicknesses were then measured by removing a portion of the film and measuring the step height of the surface profile (Dektak V400-Si). The conductivity a was then calculated by the above formula from the length of the electrode formed by the conductive layer (10 mm), the measured thickness, the resistance and the spacing (1-4 mm). As a result, the conductivity a of the conductive film was determined to be 0.7 S/cm.

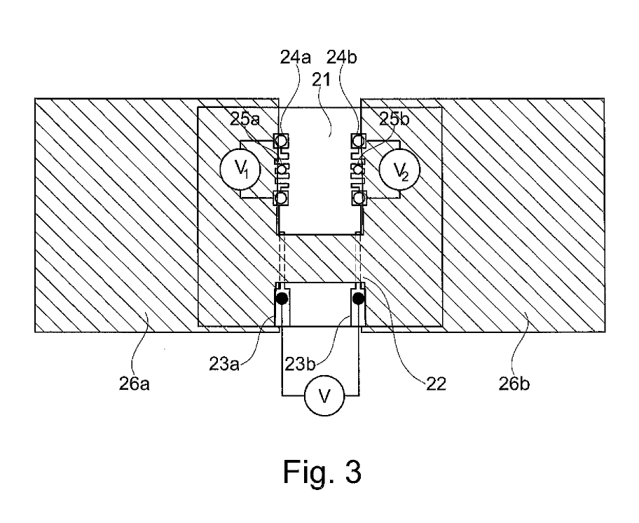

In a further experiment, the Seebeck coefficient was measured via a differential method using a themoelement in accordance with FIG. 3. For the preparation of said element, the same ink was dropcast and dried on glass substrates (21) pre-patterned by photolithography defining two electrode contacts with leadouts (23a and 23b) separated by 95 mm to form the thermoelectric material layer (22). Additionally, an insulating photoresist ‘bank’ of thickness 1 μm was defined to limit the open area of the contacts to 95 mm, thereby producing an open square between the bank and electrodes that the material can cover. Additionally two snake-like resistor features with leadouts (herein referred to as thermistors) were patterned from the metal in line with the electrodes, maintaining the same spacing of 95 mm.

The glass substrate (21) was placed upon two Peltier units (26a and 26b) which were subsequently driven in opposite polarity, one producing a hot surface and the other a cold surface. The electrical contact was made to the leadouts on the topside of the substrate using pogo pins (24a/24b) attached to a breadboard circuit and clamped to the baseplate. The circuit created allowed for a) measurement of voltage generated by sample; b) application of a small current to the thermistors; c) measurement of voltage dropped across the thermistors. Voltages were sensed using a Pico Technology TC-08 unit. Additionally, a thermocouple (25a/25b) was placed in contact (held in place by the spring force of the thermocouple) with the substrate above each thermistor and the temperature was monitored with the same TC-08 unit.

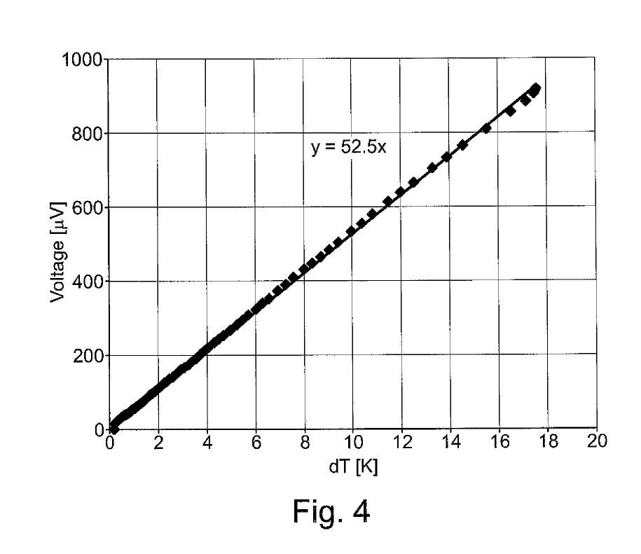

The generated voltage (V1), thermistor voltages (V2, V3) and temperature (T1, T2) were logged using Picolog software. The pettier units (26a/26b) were switched off and the temperature difference was allowed to decay to equilibrium during the logging phase. In subsequent data processing the substrate temperature at each thermistor was calculated from the change in V2 and V3 in relation to the final voltage and temperature at equilibrium (V₀, T₀) according to the equation

$$T = \frac{V - {V}_{0}}{{V}_{0} α} + {T}_{0}$$

where α is the predetermined constant of resistivity for the metal in question. The temperature difference dT was then calculated from the two thermistor temperatures. The Seebeck coefficient was then determined from the slope from the linear regression of V1 and dT. As is shown in FIG. 4, the absolute Seebeck coefficient of the sample was determined to be 52.5 μV/K.

### Example 2

In a further example, a dispersion has been prepared in accordance with Example 1, with the exception that anisole (δ_{D}=17.8; δ_{P}=4.1; δ_{H}=6.7) has been used as the first solvent for PQT12 and acetone (δ_{P}=10.4) as the second solvent for F4TCNQ. The conductivity a of the conductive film measured in a device prepared in analogy to Example 1 was determined to be 0.1 S/cm.

Accordingly, it has been shown that the formulation according to the present invention has sufficient stability for solution deposition methods and enables manufacture of conductive layers having both excellent conductivity and thermopower.

Once given the above disclosure, many other features, modifications, and improvements will become apparent to the skilled artisan.

In some examples, the first solvent may take the form of a blend of electron-rich organic compounds, each comprising one or more electron-donating groups. In other words, the first solvent may be a blend of two or more solvents, each having the hereinbefore described characteristics of the first solvent.

In some examples, the second solvent may take the form of a blend of polar solvents. In other words, the second solvent may be a blend of two or more solvents, each having the herein before described characteristics of the second solvent.

### REFERENCE NUMERALS

1a: substrate layer (high-temperature side)
1b: substrate layer (low-temperature side)
2a/2b/2c: conductor layer/electrical shunt
3: n-type leg
4: p-type leg
11: open substrate area with doped polymer ink deposited thereon
12: insulating polymer layer
13a/13d: source electrodes with leadouts for test pin contacts
13b/13c: sense electrodes with leadouts for test pin contacts
D: spacing between sense probes
L: exposed length of electrode
21: substrate
22: thermoelectric material layer
23a/23b: electrode contacts with leadouts
24a/24b: pins and circuits for measurement of generated voltage and temperature
25a/25b: thermocouple probes
26a: Peltier unit (cold)
26b: Peltier unit (hot)

1. Method of manufacturing a conductive layer, the method comprising the steps of:
dissolving an organic semiconductor polymer in a first solvent, the first solvent being an electron-rich organic compound comprising one or more electron-donating groups;
dissolving a dopant in a second solvent, the second solvent being a polar solvent;
mixing the solutions of the organic semiconductor polymer and the dopant to form a dispersion comprising doped conductive polymer particles suspended in the solvent blend; and
depositing the dispersion by a solution deposition technique to form a conductive layer, preferably by an inkjet printing, dispense printing or drop casting method; and
removing the solvent blend to form the conductive layer.

2. A method according to claim 1, wherein the first solvent is an aromatic compound comprising one or more electron-rich aromatic carbon(s) or a heterocyclic compound comprising one or more electron-rich heteroatom(s) in the heterocycle, and
wherein the second solvent is a polar solvent excluding water, the polar Hansen Solubility Parameter δ_{P} of the second solvent being higher than 8.0.

3. A method according to claim 1, wherein the organic semiconductor polymer is a conjugated organic semiconductor polymer obtained by polymerization or copolymerization of at least one compound or derivative selected from the group consisting of a thiophene compound, a pyrrole compound, an aniline compound, an acetylene compound, a p-phenylene compound, a p-phenylenevinylene compound, a p-phenyleneethynylene compound, a fluorene compound, an arylamine compound, and derivatives thereof.

4. The method according to claim 1, wherein the organic semiconductor polymer is a conjugated organic semiconductor polymer having a thiophene compound or a derivative thereof as repeating structures.

5. The method according to claim 1, wherein the dopant is a p-type dopant having a LUMO level of less than −4.3 eV relative to vacuum level as measured by square wave voltammetry, the dopant being preferably an optionally substituted tetracyanoquinodimethane (TCNQ).

6. The method according to claim 1, wherein the first solvent is selected from the group of C₆-C₁₈ aromatic hydrocarbons comprising one or more electron-donating substituents or C₄-C₁₈ heterocyclic compounds, which may be unsubstituted or comprise one or more electron-donating substituents, wherein the one or more electron-donating substituents are preferably selected from C₁-C₁₂ alkyl groups and/or a C₁-C₁₂ alkoxy groups.

7. The method according to claim 1, wherein dissolving the organic semiconductor polymer in the first solvent further comprises:
dissolving the organic semiconductor polymer in a blend comprising the first solvent and a third solvent, wherein the third solvent is an electron-rich organic compound comprising one or more electron-donating groups, and preferably has a boiling point higher than 175° C.

8. The method according to claim 1, wherein the second solvent is an organic compound comprising one or more aldehyde, ketone, carboxylic acid, ester, hydroxyl, nitrile, amide, amino, thioester, and/or thiol group(s).

9. The method according to claim 1, wherein the polar Hansen Solubility Parameter δP_{P} of the second solvent is higher than 9.0, preferably higher than 10.0; the polar solvent being preferably selected from acetone or acetonitrile.

10. The method according to claim 1, wherein the weight ratio of organic semiconductor polymer:dopant is in the range of from 5:1 to 20:1, preferably in the range of from 7:1 to 12:1.

11. The method according to claim 1, wherein the volume ratio of the first solvent and the second solvent is from 1:1 to 4:1, preferably from 2:1 to 3:1.

12. Conductive layer manufactured by the method according to claim 1, having an electrical conductivity of 0.1 S/cm or more and an absolute Seebeck coefficient of 40 μV/K or more.

13. Thermoelectric module comprising the conductive layer according to claim 12.

14. A formulation comprising a doped conductive polymer dispersed in a solvent blend, the solvent blend comprising a first solvent and a second solvent,
wherein the first solvent is an aromatic compound comprising one or more electron-rich aromatic carbon(s) or a heterocyclic compound comprising one or more electron-rich heteroatom(s) in the heterocycle, and
wherein the second solvent is a polar solvent excluding water, the polar Hansen Solubility Parameter δ_{P} of the second solvent being higher than 8.0.

15. The formulation according to claim 14, wherein the polymer is a conjugated polymer obtained by polymerization or copolymerization of at least one compound or derivative selected from the group consisting of a thiophene compound, a pyrrole compound, an aniline compound, an acetylene compound, a p-phenylene compound, a p-phenylenevinylene compound, a p-phenyleneethynylene compound, a fluorene compound, an arylamine compound, and derivatives thereof.

16. The formulation according to claim 14, wherein the polymer is a conjugated polymer having a thiophene compound or a derivative thereof as repeating structures.

17. The formulation according to claim 14, wherein the dopant is a p-type dopant having a LUMO level of less than −4.3 eV relative to vacuum level as measured by square wave voltammetry, the dopant being preferably an optionally substituted tetracyanoquinodimethane (TCNQ).

18. The formulation according to claim 14, wherein the first solvent is selected from the group of C₆-C₁₈ aromatic hydrocarbons comprising one or more electron-donating substituents or C₄-C₁₈ heterocyclic compounds, which may be unsubstituted or comprise one or more electron-donating substituents, wherein the one or more electron-donating substituents are preferably selected from C₁-C₁₂ alkyl groups and/or a C₁-C₁₂ alkoxy groups.

19. (canceled)

20. The formulation according to claim 14, wherein the second solvent is an organic compound comprising one or more aldehyde, ketone, carboxylic acid, ester, hydroxyl, nitrile, amide, amino, thioester, and/or thiol group(s).

21-24. (canceled)

25. Use of the formulation according to claim 14 in the manufacturing of a thermoelectric module.
